(19) United States
(12) Patent Application Publication
(10) Pub. No.: US 2014/0327426 A1
(43) Pub. Date: Nov. 6, 2014

(54) PULSE FORMING NETWORK (PFN) HAVING MULTIPLE CAPACITOR UNITS FOR FORMING A PULSE HAVING A MULTI-LEVEL VOLTAGE AND A METHOD OF FORMING SUCH A PULSE

(71) Applicants: Lightsquare Ltd., Nahal Oz (IL); Moshe SHTERZER, Herzlia (IL)

(72) Inventor: Moshe Shterzer, Herzlia (IL)

(21) Appl. No.: 14/370,241

(22) PCT Filed: Jan. 3, 2013
(86) PCT No.: PCT/IL2013/050012

§ 371 Date: Jul. 2, 2014

Related U.S. Application Data
(60) Provisional application No. 61/583,208, filed on Jan. 5, 2012.

(51) Int. Cl. H03K 3/35

(52) U.S. Cl. CPC H03K 3/35
USPC 323/364

(57) ABSTRACT

A method of generating a patterned pulse. The method comprises charging a plurality of capacitor units with a plurality of charges, and sequentially coupling the plurality of charged capacitor units to at least one electrical regulator so as to allow delivering a regulated energizing pulse having a desired multi-level voltage waveform to a load. The electrical regulator is connected to a load.

### FIELD AND BACKGROUND OF THE INVENTION

The present invention, in some embodiments thereof, relates to a pulse forming network (PFN) and, more particularly, but not exclusively, to a PFN having multiple capacitor units.

A pulse forming network (PFN) is an arrangement of electrical components that is set to accumulate electrical energy over a period and releases the accumulated energy in the form of a pulse of comparatively short duration for various pulsed power applications. In practice, a PFN is charged by means of a high voltage power source, and then rapidly discharged into a load. The load may be a high power microwave oscillator, such as a klystron or magnetron, a flash lamp such as a Xenon Pulse lamp, Filament Wire and filament lamp and/or an electromagnet.

During the last years various PFN have been developed. For example, U.S. Pat. No. 6,965,215 describes capacitor based pulse forming networks and related methods are provided which require fewer inductors are that pulsed more frequently to provide a smaller, lower mass, and lower inductance pulse forming network having better pulse shaping characteristics than conventional pulse forming networks. In one implementation, the invention can be characterized as a capacitor based pulse forming network comprising a plurality of inductors adapted to be coupled to a load, a plurality of capacitor units, and a plurality of switches. Each switch couples a respective capacitor unit to a respective inductor, wherein multiple capacitor units are coupled to each inductor by separate switches. The plurality of switches are adapted to non-simultaneously discharge the multiple capacitor units to provide non-simultaneous pulses through a given inductor to the load and not through other inductors. The non-simultaneous pulses form at least a portion of an output pulse waveform to the load.

U.S. Pat. No. 7,514,820 describes a capacitor based pulse forming networks and methods which require fewer inductors are that pulsed more frequently to provide a smaller, lower mass, and lower inductance pulse forming network having better pulse shaping characteristics than conventional pulse forming networks. In one implementation, the invention can be characterized as a capacitor based pulse forming network comprising a plurality of inductors adapted to be coupled to a load, a plurality of capacitor units, and a plurality of switches. Each switch couples a respective capacitor unit to a respective inductor, wherein multiple capacitor units are coupled to each inductor by separate switches. The switches are adapted to non-simultaneously discharge at least some of the multiple capacitor units to provide non-simultaneous pulses through a given inductor to the load and not through other inductors. The non-simultaneous pulses form at least a portion of an output pulse waveform to the load.

### SUMMARY OF THE INVENTION

According to some embodiments of the present invention, there is provided a pulse forming network (PFN) which comprises at least one electrical regulator connected to a load, a plurality of capacitor units set to store a plurality of charges in a plurality of working output voltages, a plurality of switches, each adapted to couple electrically one of the plurality of capacitor units to the at least one electrical regulator, and a control unit which operates the plurality of switches to discharge the plurality of charges into the load, via the at least one electrical regulator, in sequence ordered to form a regulated energizing pulse having a desired multi-level voltage waveform.

Optionally, each the capacitor unit is energized by a power source adapted to the respective the working output voltage

Optionally, the at least one electrical regulator being adapted to regulate the level of each the working output voltage to a voltage level of no less than 90% of the minimum of the working output voltage when discharged into the at least one electrical regulator.

Optionally, the desired multi-level voltage waveform comprising the plurality of different working output voltages.

Optionally, the control unit monitors the pulse to identify a deviation from at least one of a reference pulse and a previously recorded pulse generated by the PFN.

More optionally, the control unit identifies a malfunction in at least one of the plurality of capacitor units according to an analysis of the waveform and outputs an indication which indicates which of the plurality of capacitor units malfunctions.

More optionally, the at least one electrical regulator is adjusted according to a train pulse which is adjusted according to a feedback control from at least one of the plurality of capacitor units, the control unit identifies a malfunction in at least one of the plurality of capacitor units according to an analysis of the train pulse and outputs an indication which indicates which of the plurality of capacitor units malfunctions accordingly.

Optionally, the plurality of capacitor units are detachably connected to a supporting structure.

Optionally, the control unit is set to trigger a number of the plurality of capacitor to units simultaneously.

Optionally, the control unit is set to trigger the plurality of capacitor units sequentially.

Optionally, the control unit is set to monitor at least some of the plurality of capacitor units and to output an indication which indicates which of the plurality of capacitor units does not work properly.

According to some embodiments of the present invention, there is provided a pulse forming network (PFN) which comprises a plurality of capacitor units, a plurality of charging units each electrically connected to another of the plurality of capacitor units, the plurality of charging units being set to charge the plurality of capacitor units with a plurality of electrical charges having a plurality of voltages, at least one electrical regulator electrically connected to a load, and a plurality of switches each coupling one of the plurality of capacitor units to the at least one electrical regulator and electrically connected to be controlled by a control unit.

Optionally, each switch coupling one of the plurality of capacitor units via an anti reversing diode.

Optionally, the at least one electrical regulator comprises a plurality of electrical regulators, each the switch coupling one of the plurality of capacitor units to another of the plurality of electrical regulators.

Optionally, the plurality of capacitor units are set to be electrically charged with a plurality of different electrical charges.

Optionally, the plurality of switches are sequentially triggered to receive a respective the electrical charge from a respective the capacitor in a sequential order, forming a patterned energizing pulse.

More optionally, the patterned energizing pulse having a square waveform.

Optionally, the at least one electrical regulator comprises a voltage regulator.

Optionally, the at least one electrical regulator comprises a current regulator.

Optionally, the PFN further comprises a control unit, coupled to control the plurality of switches.

More optionally, the control unit is set to trigger a number of the plurality of to switches simultaneously.

More optionally, the control unit receives a requested charge level for the load and selects the number of switches according to the requested charge level.

Optionally, the PFN further comprises a control unit, coupled to monitor a charging rate in each the capacitor and outputs an indication which indicates which of the plurality of capacitor units does not charge properly.

Optionally, each of at least some of the plurality of capacitor units are coupled to an indicator which indicates if it is working properly.

Optionally, the plurality of capacitor units are detachably connected to the PFN.

Optionally, each the capacitor is iteratively charged.

Optionally, the at least one electrical regulator comprises a buck converter.

Optionally, the buck converter having an inducer which is electrically wired in parallel to the load.

Optionally, the at least one electrical regulator is a member of a group consisting of a switching regulator and an analog regulator.

According to some embodiments of the present invention, there is provided a method of generating a patterned pulse. The method comprises a) charging a plurality of capacitor units with a plurality of charges, and b) sequentially coupling the plurality of charged capacitor units to at least one electrical regulator so as to allow delivering a regulated energizing pulse having a desired multi-level voltage waveform to a load. The electrical regulator is connected to a load.

Optionally, the method further comprises repeating the a) and b) so as to charge the load continuously.

According to some embodiments of the present invention, there is provided a pulse forming network (PFN) which comprises a plurality of modules each comprising: a capacitor unit which stores a charge, a charging unit electrically connected to and set to charge the capacitor unit, an electrical regulator electrically connected to a load, and a switch coupling the capacitor unit to the electrical regulator.

The PFN further comprises a control unit which operates each the switch of the plurality of modules to discharge each the charge into the load in a sequence ordered to form a regulated energizing pulse having a desired multi-level voltage waveform. Each regulator of the plurality of modules is connected to a common load.

Optionally, the plurality of modules are detachably connected to a supporting element.

Optionally, the plurality of modules having inverted polarity and set interchangeably energize the load with alternating current.

Optionally, the PFN further comprises a circuitry adapted to connect simultaneously and in parallel at least some of the plurality of the modules to the load.

Optionally, the PFN further comprises a circuitry adapted to connect at least some of the plurality of the modules to the load in a row.

Optionally, each the module having a plurality of electrical regulators connected in parallel to the load.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system.

In an exemplary embodiment of the invention, one or more tasks according to exemplary embodiments of method and/or system as described herein are performed by a data processor, such as a computing platform for executing a plurality of instructions.

Optionally, the data processor includes a volatile memory for storing instructions and/or data and/or a non-volatile storage, for example, a magnetic hard-disk and/or removable media, for storing instructions and/or data.

Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1A is a schematic illustration of a PFN having a plurality of modules, each with a capacitor unit connected to a load via an electrical regulator, according to some embodiments of the present invention;

FIG. 1B is an illustration depicting an exemplary electric circuit which is wired to form a PFN as depicted in FIG. 1A, according to some embodiments of the present invention;

FIG. 1C is an illustration depicting an exemplary multi module electric circuit which is wired to form a PFN, similar to the depicted in FIG. 1A, where each module have two or more electric regulator, according to some embodiments of the present invention;

FIG. 1D is an illustration depicting an exemplary multi module electric circuit which is wired to form a PFN, similar to the depicted in FIG. 1A, where the modules are set to circularly charge the load, according to some embodiments of the present invention;

FIG. 2 is a schematic illustration of another PFN having a plurality of modules, according some embodiments of the present invention;

FIG. 3A is a schematic illustration which depicts a PFN having the components depicted in FIG. 1A with a central electrical regulator, according to some embodiments of the present invention;

FIG. 3B is an exemplary electric circuit that is wired to form the PFN depicted in FIG. 3A, according to some embodiments of the present invention;

FIG. 3C is an exemplary electric circuit that is wired to form a PFN having regulators with buck converters which are parallel to a load (the load connected in parallel to the inductor), according to some embodiments of the present invention;

FIGS. 3D-3F are graphs depicting a simulation of a square waveforms having short and high picks which are generated using a PFN as depicted in FIG. 3C, according to some embodiments of the present invention;

FIG. 3G is an exemplary electric circuit that is wired to form a PFN for energizing a load with an alternating current by connecting, interchangeably, different modules with inverted polarity, according to some embodiments of the present invention;

FIG. 3H is a graph depicting a simulation of a square waveforms generated having short and high picks which are generated using a PFN as depicted in FIG. 3C, according to some embodiments of the present invention;

FIG. 4 is a flowchart of a method of generating a patterned pulse from a plurality of charges having increased voltage, according to some embodiments of the present invention; and

FIGS. 5, 6, and 7 are graphs depicting simulations of increasing, multi-level, and decreasing square waveforms which are generated according to the method depicted in FIG. 4 and/or by the PFNs which are similar to the PFNs depicted in FIGS. 1-3, according to some embodiments of the present invention.

### DESCRIPTION OF EMBODIMENTS OF THE INVENTION

The present invention, in some embodiments thereof, relates to a pulse forming network (PFN) and, more particularly, but not exclusively, to a PFN having multiple capacitor units.

According to some embodiments of the present invention, there is provided a pulse forming network (PFN) set to deliver an energizing pulse having a regulated multi-level voltage waveform formed by a plurality of capacitor charge flows, to a load. The energizing pulse is optionally formed charging a set of capacitor units with different voltages and discharging them, sequentially, each via an electric regulator, to the load.

The PFN optionally comprises one or more electrical regulators which are electrically connected to a load and capacitor units which are set to store a plurality of charges in a plurality of different level working voltages. The PFN includes a plurality of switches, or a switch which functions as a plurality of switches. Each switch is adapted to connect (or disconnect) electrically one of the plurality of capacitor units to one of the electrical regulators or to a central electrical regulator. The PFN is controlled by a control unit which operates the switches. The control unit controls the switches to discharge the charges of the capacitor units into the load, via the electrical regulators, in a sequence ordered to form an energizing pulse having a desired regulated multi-level voltage or current waveform, for example a desired square and variables steps waveform.

Optionally, each one of the capacitor units is charged by a power source, a charger, which is adapted to its working output voltage.

Optionally, each capacitor unit is connected to an electric regulator, for example a switching (electronic) regulator or an analog (electronic) regulator, which is adapted to its working output voltage. For example, the regulator may be adapted to regulate the voltage level of the discharge of the respective capacitor unit to a voltage level of no less that minimum therefrom.

Optionally, a central regulator is wired to regulate all the charges. In such an embodiment, the central regulator may be controlled by the control unit so that its regulation is adapted in real time to the voltage level of the discharging capacitor unit.

Optionally, the PFN comprises a plurality of modules, each having a power source which is connected to a capacitor unit which is connected, via switch to an electric regulator. All the modules are connected to a common load via the respective regulators. All the components of each module are optionally adjusted to a certain working output voltage. In such a manner, the capacitor unit is charged by a power source which is adapted to its working output voltage and therefore no or only a little of charging power is wasted. In addition, as the capacitor unit is connected to a regulator that is set to regulate its working output voltage, only little amount of charged power is wasted during the voltage regulation, for example about 10% of the input voltage, optionally depends the type of the regulator, during the discharging of the capacitor.

Optionally, each module and/or capacitor unit is connected to a tester circuit which checks on the presence or absence of one or more defectives in the module, in real time.

Optionally, each module is detachably connected to the PFN so it may be replaced of needed by a functioning module.

According to some embodiments of the present invention, there is provided method of generating an energizing pulse, for example using the PFN that is outlined above and described below. The method is based on charging a plurality of capacitor units with a plurality of charges and sequentially coupling the plurality of charged capacitor units to an electrical regulator connected to a load (either a central regulator or one of a set of electrical regulators) so as to deliver to the load an energizing pulse having a regulated multi-level voltage with a desired waveform.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

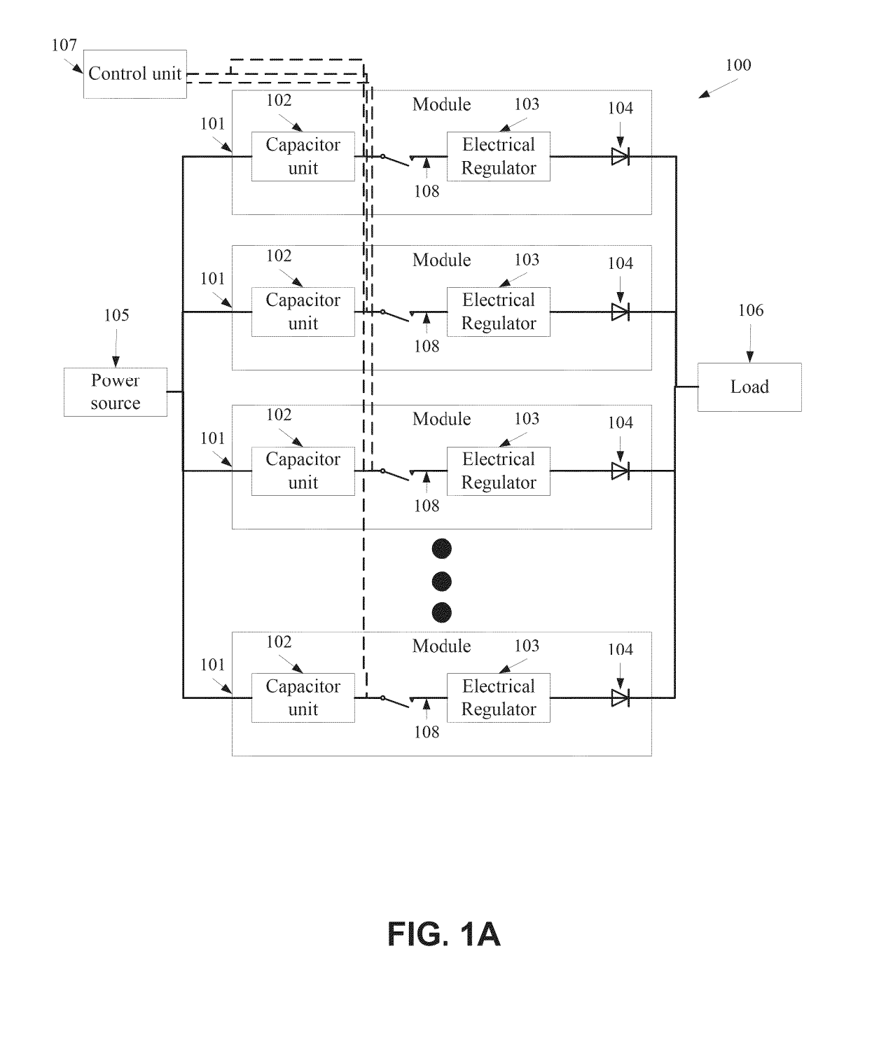

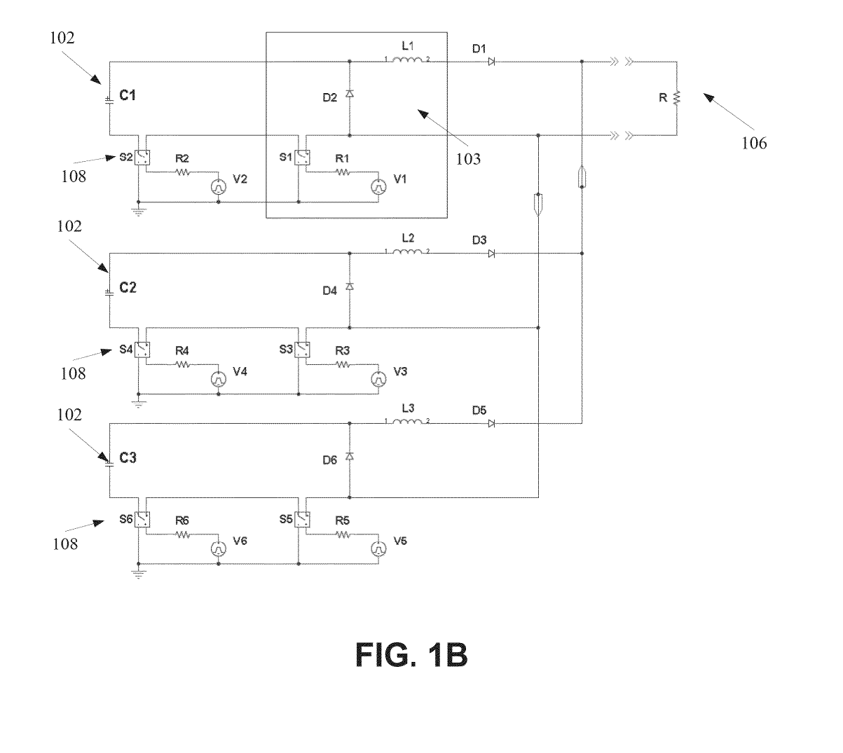

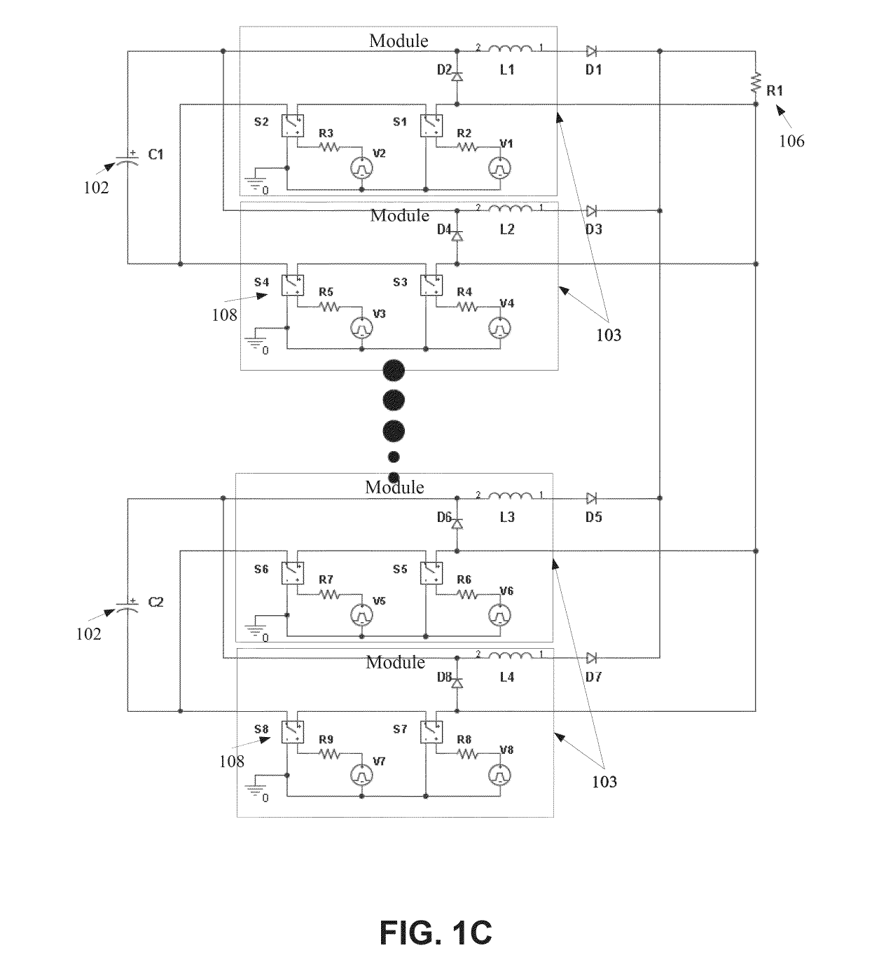

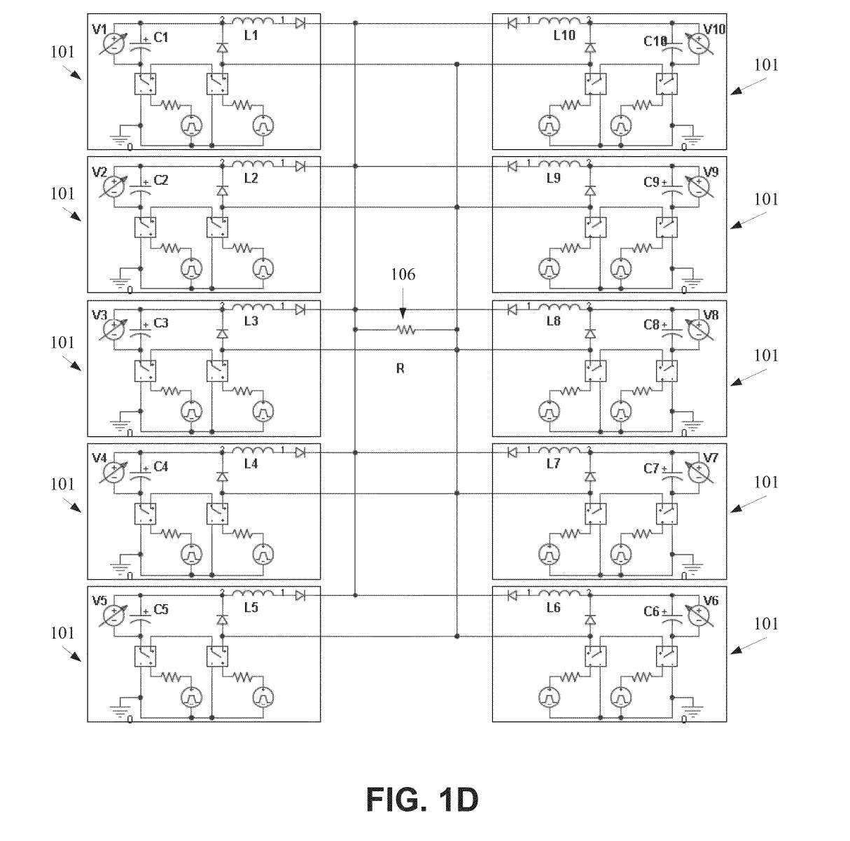

Reference is now made to FIG. 1A, which is a schematic illustration of a PFN 100 having a plurality of modules 101, each having a capacitor unit 102 wired to be connected to a load 106 via an electrical regulator 103 and a switch 108, according to some embodiments of the present invention.

Optionally, the capacitor units 102 have different output voltages. In such a manner, the PFN 100 may energize the load 106 by producing and delivering a plurality of sequential regulated charges that form a patterned energizing pulse having a regulated multi-level voltage waveform. As used herein, energizing means supplying with electrical power. The PFN 100 may be used to charge the capacitor units 102 with energy which is ten times or even more of the input charge. In use, the capacitor units 102 of the PFN 100 accumulate electrical energy over a comparatively long time and then sequentially release the accumulated electrical energy, under the control of the control unit 107, in the form of a relatively square pulse of comparatively short duration.

The discharge level of each capacitor 102 is correlated with the voltage regulation level of the respective electrical regulator 103. For example, the electrical to regulator 103 brings the discharged energy to a voltage level to the load that is about 90% of the minimum input discharged voltage level,

Optionally, the current of the discharged energy is higher than the feed current which loads the capacitor units 102. An exemplary load 106 may be a high power microwave oscillator, such as a klystron or magnetron, a flash lamp, such as a Xenon lamp, or Filament Wire lamp, a Driver Electric Motor in acceleration moment, an electric car load, such as a motor, a laser diode, an electromagnet, a Marx generator, a pulsed laser source, such as CO₂ TEA laser source, a radar, a fusion generator (currently in research), a particle accelerator, Sun Simulator, a portable Sun Simulator which is energized by a DC source, Dimming Ballast driver for HID CW lamp, and/or any load which is energized with a patterned energizing pulse having a regulated multi level voltage (having two or more voltage DC or AC polarity levels). The multi-level voltage waveform may have various shapes, such as a square waveform, a Gaussian waveform and/or a thin integrated circuit or any other non-sinusoidal waveform, such as rectangular waves waveform, ramp waves waveform, triangle waves waveform, spiked waves waveform and sawtooth waves waveform.

According to other embodiments of the present invention the capacitor units 102 have a common or different output voltage level. In such a manner, the PFN 100 may energize the load 106 with a pulse having a substantially uniform regulated voltage. An exemplary electric circuit that is wired to form the PFN depicted in FIG. 1A, according to some embodiments of the present invention, is depicted in FIG. 1B.

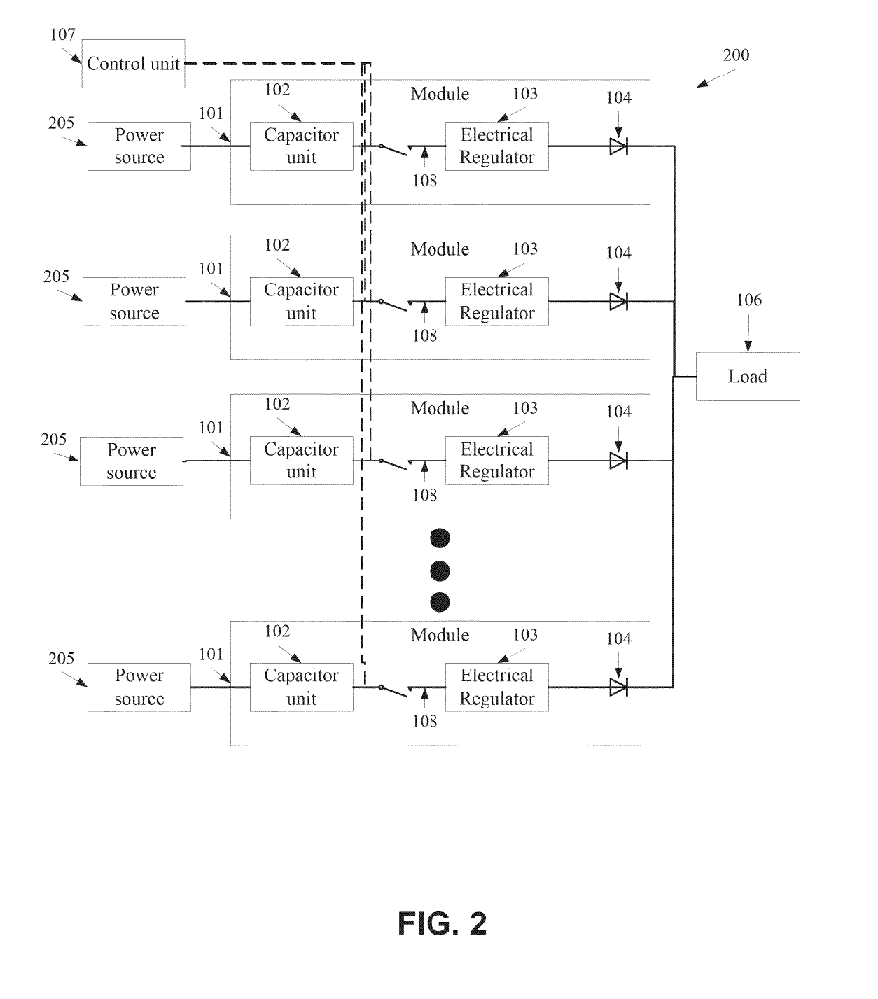

The capacitor units 102, which are charged by the one or more insolated power sources, are optionally high voltage power sources. For example, in FIG. 1A, the capacitor units 102 are charged by a single power source 105. Such a power source 105 is a shared power source 105 which charges a number of capacitor units 102. In FIG. 2, which is a schematic illustration of another PFN 100 having the plurality of modules 101, according some embodiments of the present invention, each capacitor unit 102 is connected to another power source 205. Each power source 205, for example a charger, is separately connected to one of the capacitor units 102 or to a group of capacitor units 102 having a common working output voltage level. In such a manner, while one or more capacitor units 102 are charged by one power source one or more other capacitor units 102 are charged by another. In such embodiments, each power source 205 is adapted to the voltage level of the fed capacitor unit 102. As the voltage level of the charger and the capacitor are adapted to the output load, less energy is wasted during the charging of the capacitor units 102. The power source(s) 105, 205 may be high power sources for example chargers which are connected to a power line and/or a set of batteries low power sources.

Optionally, some or all of the modules 101 are connected to a circuitry which allows simultaneously connecting some or all of them to the load 106. In such a manner, the output of the modules 101 may be combined to form a discharge with a higher current than the current of each one of them. The circuitry connects the modules 101 in parallel so that the output thereof is an accumulation of high currents. It should be noted that as the output of each module 101 is regulated, the summed output is also regulated.

Additionally or alternatively, some or all of the modules are connected in a circuitry which allows summing the outputs thereof to increase to voltage of the discharge before energizing the load 106. In such a manner, the output of the modules 101 may be combined to form a discharge with a higher voltage than the voltage of each one of them. The circuitry connects the output modules 101 in a row in series, one after the other, so that the output thereof is an accumulation of voltages and high voltage is applied to the load. It should be noted that as the output of each module 101 is regulated, the summed output is also regulated.

Optionally, a diode 104, such as an anti reversing diode, is provided between the electrical regulator 103 and the load 106 to keep the capacitor units 102 from becoming a load when each module powers the load with a different charge.

Optionally, each capacitor unit 102 is connected to a local indicator or test circuit, which is set to indicate whether it functions properly or not.

Optionally, the indicator circuit comprises a light emitting diode (LED) that is active when the capacitor operates properly.

Each electrical regulator 103, which may be set to regulate voltage and/or current, for example a switching (electronic) regulator or an analog regulator, maintains a constant voltage level and/or current. The regulated voltage may be set automatically or selected by the control unit 107, as described below. Depending on the design, the electrical regulator 103 may be used to regulate one or more direct current (DC) voltages and/or currents from the capacitor units 102. As the electrical regulator 103 maintains a constant voltage level and/or current, the output of each one of the modules 101, as received by the load 106, can be evaluated in advance. All the electrical regulators 103 are connected to the load 106. It should be noted that as the charges having known and constant voltages, the range of voltages which have to be regulated is limited and therefore low cost electrical regulators with are set to regulate a limited dynamic range of Δ input voltage may be used. It should further be noted that electromagnetic interferences (EMC) as a reduced effect on the PFN 100 as simultaneous and non-simultaneous operation of electrical regulators 103 which are limited in their working output voltage level and/or designated power sources are used. Moreover, when a plurality of electrical regulators 103 is used, current flows to the load 106, through each electrical regulator 103, in relatively short intervals. Thus, relatively thin wires and/or a small power devices and integrated circuit may be used that conduct the regulated charges the load 106.

Optionally, the capacitor unit 102 of some or all of the modules 101 is connected to a number of electrical regulators, each as depicted in 103. For example, FIG. 1C depicts an exemplary multi module electric circuit which is wired to form a PFN, similar to the depicted in FIG. 1A, where each module 101 have two (or more) electric regulators 103. This allows using capacitor units 102 with high voltage potential which have higher functionality duration.

According to some embodiments of the present invention, the PFN 100 is set to continually generating an energizing pulse having a regulated multi-level voltage.

In such an embodiment, the charging and discharging periods of each capacitor unit 102 are adapted so that discharges are constantly transferred to the load 106. For example of the N capacitor units 102 are used and the charging period per capacitor unit 102 is X, than (N−1)*X denotes the charging period. For example, FIG. 1D is an illustration depicting an exemplary multi module electric circuit which is wired to form a PFN, similar to the depicted in FIG. 1A, where all the modules are connected to a common load and set to circularly charge the load 106. When the load is continuously charged, the power source considers the load 106 as a resistor having a fixed resistance value and not as a load with variable consumption. When the load is continuously to charged, pulses may have variable forms and the length of the pulse periods may vary from null to infinity. Such an exemplary multi module electric circuit may be used to energize a load, such as an engine, without power consumption picks.

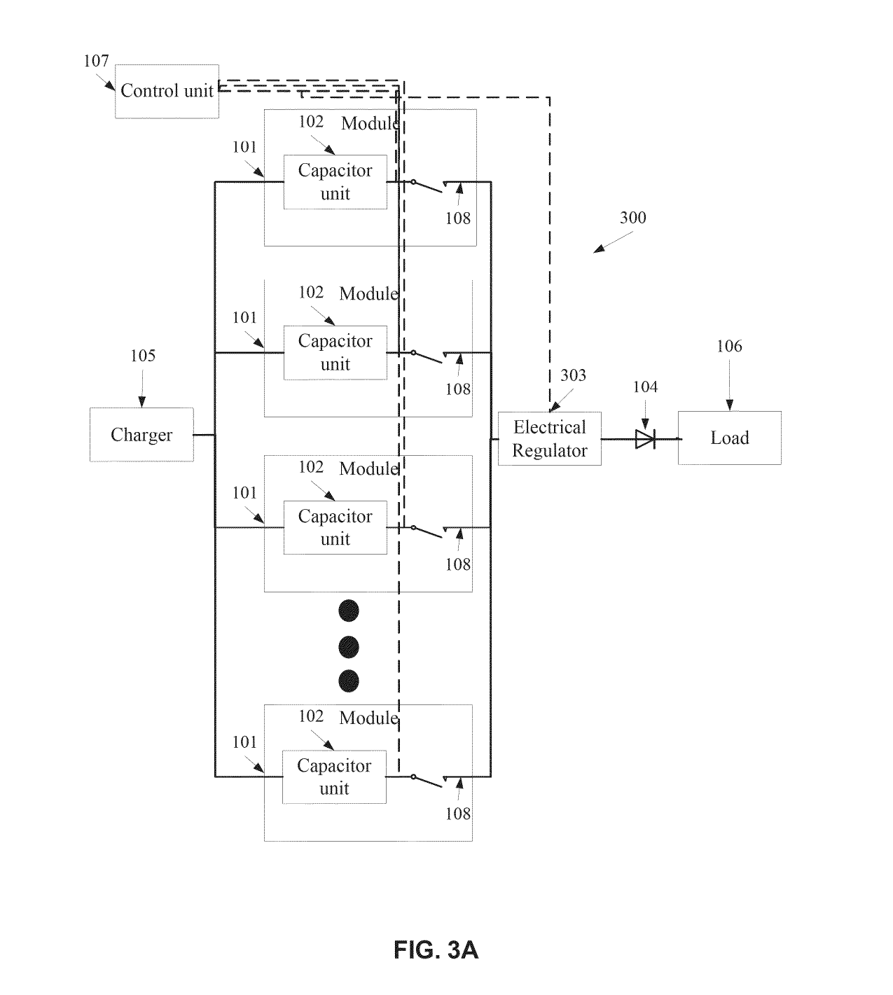

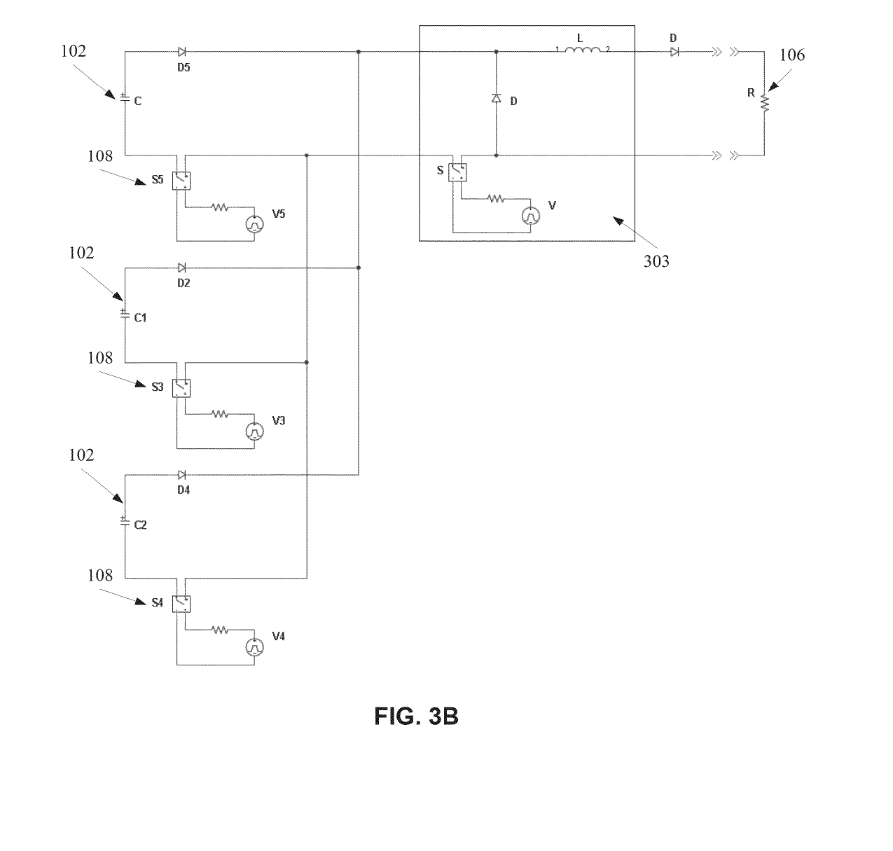

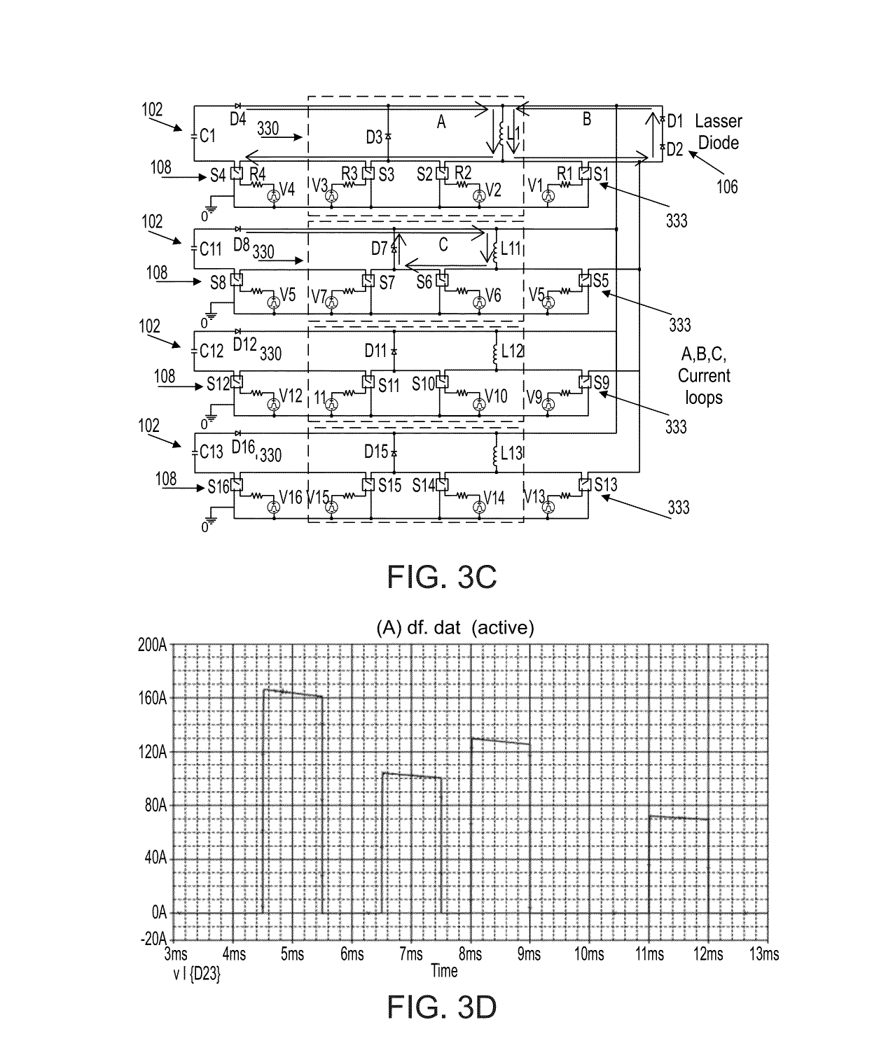

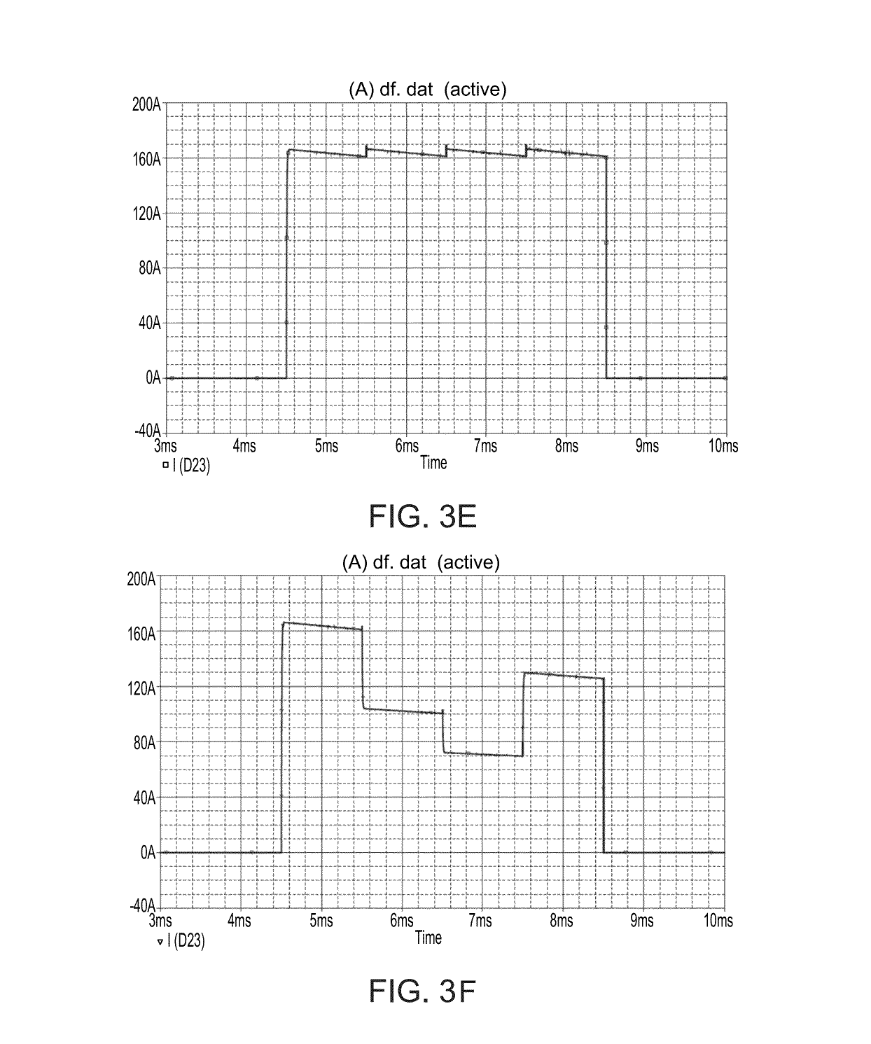

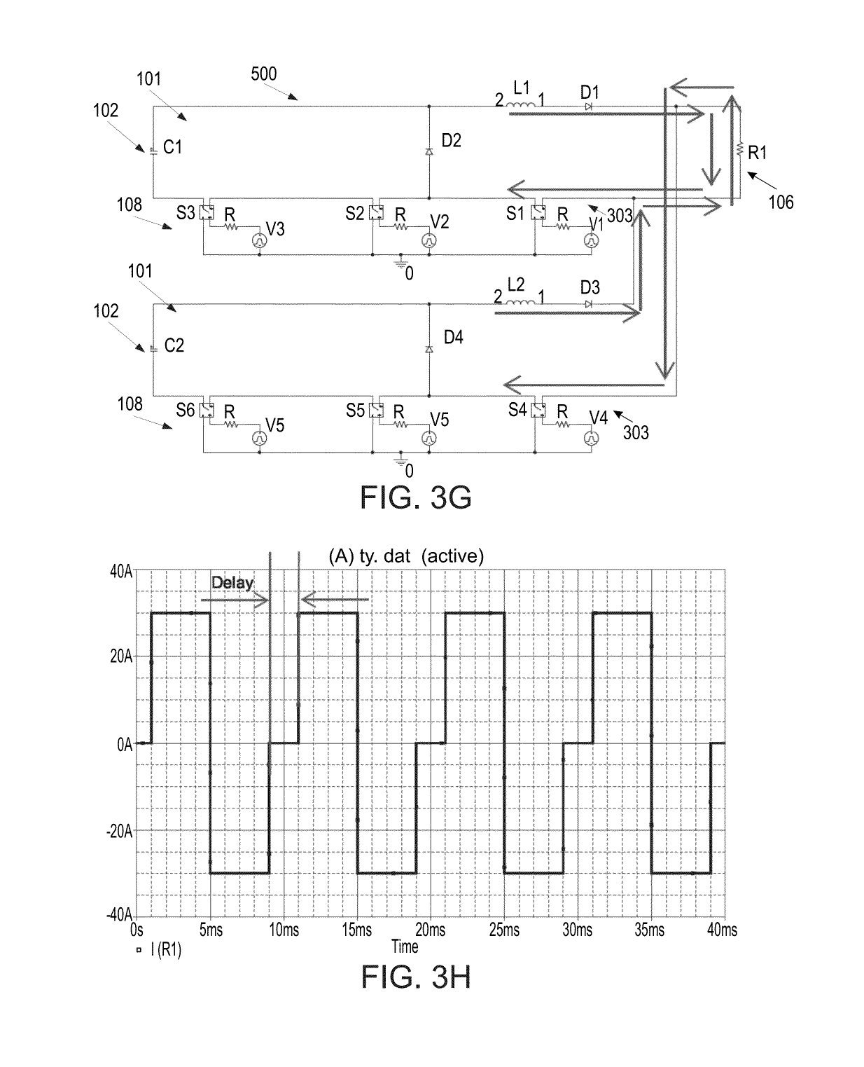

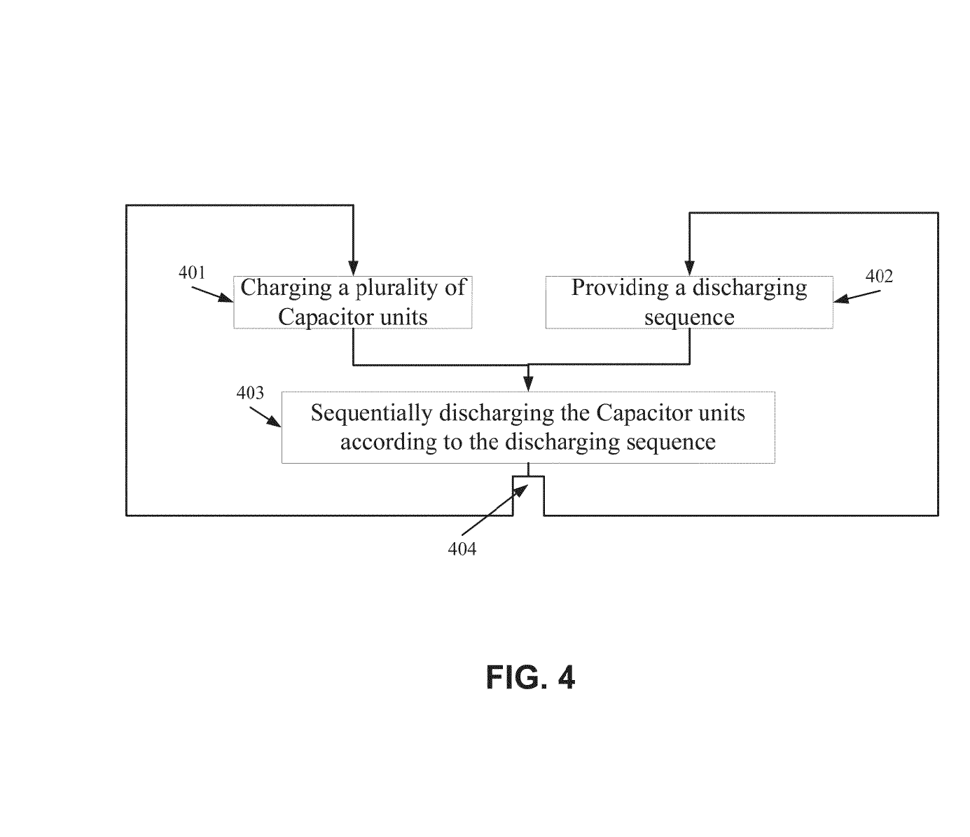

Reference is now also made to FIG. 3A, which is a schematic illustration that depicts a PFN 300 having the components depicted in FIG. 1A with a central electrical regulator 303 instead of electrical regulators 103, according to some embodiments of the present invention. For example, an electrical regulator 303 which includes a step down DC-to-DC convertor, such as a buck converter may be used. An exemplary electric circuit that is wired to form the PFN depicted in FIG. 3A, according to some embodiments of the present invention, is depicted in FIG. 3B. In such an embodiment, all the capacitor units 102 are wired to discharge their charges into the load 106 via the central electrical regulator 303. In such an embodiment, the central electrical regulator 303 may be controlled by a control unit 107 so as to regulate the voltage that is discharged from the capacitor units 102 in a variable manner.

According to some embodiments of the present invention, the PFN 100, 200, 300 is adapted to energize a load that is connected in parallel to the inductor (for example coil) of the buck convertor of the electrical regulator(s) 103. This allows discharging energy having high ampere in a short time to the load 106. For example, reference is now made to FIG. 3C, which is an exemplary electric circuit that is wired to form a PFN having regulators with buck convertors which are wired in parallel to the load 106, which is optionally an array of laser diodes, according to some embodiments of the present invention. For example, the circuit segments marked with the numeral 330 are regulators which include a buck convertor. The inductor is optionally grounded. When any of switches 333 are in a close state, the load 106 is energized in parallel to the respective inductor (L1, L2, L3, and L4). In use, a capacitor unit, such as C₁, is instructed by switch, for example S₄, to the buck converter. When the switch of the buck converter, for example S₃, is connected a charge flow as depicted in the circle which is marked with the letter A and when this switch is disconnected a charge flow as depicted in the circle which is marked with the letter B. This allows charging the respective inductor (cycle A) and storing the charged respective inductor (cycle B) until it is released in parallel to the load, as depicted in the circle which is marked with the letter C. This allows charging the load with an energizing pulse having a regulated multi-level voltage with a desired waveform having short and high picks, for example as depicted in FIGS. 3D and 3F.

In addition, this allows charging the load with an energizing pulse having a regulated multi-level voltage with a desired waveform having sequential high picks, for example as depicted in FIG. 3E.

According to some embodiments of the present invention, the PFN 100, 200, 300 is adapted to energize a load with an alternating current by connecting, interchangeably, different modules 101 with inverted polarity. For example, FIG. 3I depicts a PFN 500, which is similar to the PFN depicted in FIGS. 1A-1B wherein two modules 101 are connected to energize interchangeably the load 106 with an alternating current. This allows charging the load 106 with an energizing pulse having a regulated multi-level voltage with a desired waveform with positive and negative amplitudes, for example as depicted in FIG. 3H. This allows charging a load such as a high intensity discharge (HID) lamp for light dimming. When a delay is set between the connection of the different modules 101, the root mean squared (RMS) in the load 106 is reduced and so the consumed power is also reduced. During the delay period, the decrease of the plasma is relatively slow. This allows a delay up to about 50% in a frequency of about 100 KHz without any substantial reduction in the quality of the color of the light emitted from the load 106.

According to some embodiments of the present invention, the control unit 107 is wired to control and/or to monitor the modules 101. As used herein, wired means connected in any manner that allows establishing communication between modules. The control unit 107, which optionally includes a microcontroller, is optionally wired to control, for example to open and to close, each one of the switches 108. For example, the control unit 107 determines the timing and/or the length of the period in which each switch is close and/or open. In such a manner, the control unit 107 controls the sequence and/or number of capacitor units 102 which are connected to power the load in series or parallel. For example, the number of switches may be changed according to the required voltage and power level.

Optionally, the control unit 107 controls the switches 108 to connect the capacitor units 102 sequentially and non-sequentially so as to form a pulse having a uniform voltage waveform or a waveform having a multi-level voltage, for example as described above.

Optionally, the control unit 107 controls the switches 108 to connect and/or disconnect a number of capacitor units 102 simultaneously. In such a manner, the summed charges of the simultaneously connected capacitor units 102 are propagated to the load 106 and the current of the charge which energizes the load is increased.

Optionally, the control unit 107 controls the switches 108 so that the number of capacitor units, which are connected to discharge the load 106 each time, varies in a different point in time. In such a manner, the pulse that energizes the load 106 has a regulated multi-level voltage pattern.

Optionally, the control unit 107 is connected to the load 106 so as to measure changes in its impedance. In such a manner, the control unit 107 may adapt the modules 101 or any of its components (102, 103) to the changes of the impedance.

Optionally, the control unit 107 controls the charges which are charged in each one of the connected capacitor units 102, for example by instructing the powers sources 105, 205 to charge the capacitor units 102 with a charge having a certain voltage.

Optionally, the control unit 107 controls the voltage regulation level at the one or more electrical regulators 103.

Optionally, the control unit 107 controls the switches 108, powers sources 105, 205, and/or one or more electrical regulators 103 to deliver an energizing pulse having a multi-level voltage waveform. For example, the control unit 107 matches between the charging voltage level that is provided by a certain charger 205 to the potential voltage level of the certain charged capacitor unit 102 and/or between the charge that is charged in the certain charged capacitor unit 102 and the voltage regulation level that is set by the respective electrical regulator 103. The control allows avoiding redundant charging and/or redundant voltage regulation and therefore reduces the energy lose.

Optionally, each capacitor unit 102 is charged by a charge adapted to its capacity, for example to a certain voltage level so that the level of the discharge thereof is regulated, by the electrical regulator 103, to a voltage level that is no less than about 90% of the minimum level of the discharge. For example a charge of 300 v Minimum volts is regulated to a stable charge of about 270 v volts.

Optionally, the control unit 107 may adjust the discharge sequence in which it opens and/or closes the switches, adjust the number of switches it closes and/or open simultaneously, adjust the voltage level that is charged into the capacitor units, adjust the and/or adjust the regulation level of the one or more electrical regulators 103.

Optionally, these adjustments are preformed according to instructions received from a central computing unit (CPU), such as a desktop computer, a laptop, a tablet, and/or Smartphone, optionally to separately control circuits in every module, for example from a control application which is installed thereon. It should be noted that the control unit may comprise a number of separate control units.

The control may be done by a central computing unit which receives a feedback from the load 106.

Optionally, a number of control units are installed in PFN 100. Each control unit is installed in another module 101 and monitors the charges which are released from the respective capacitor unit 102 and/or electric regulator 103.

The control unit 107 may be a microcontroller, such as the Microchip family microcontroller and/or Msp430 Ti family microcontroller.

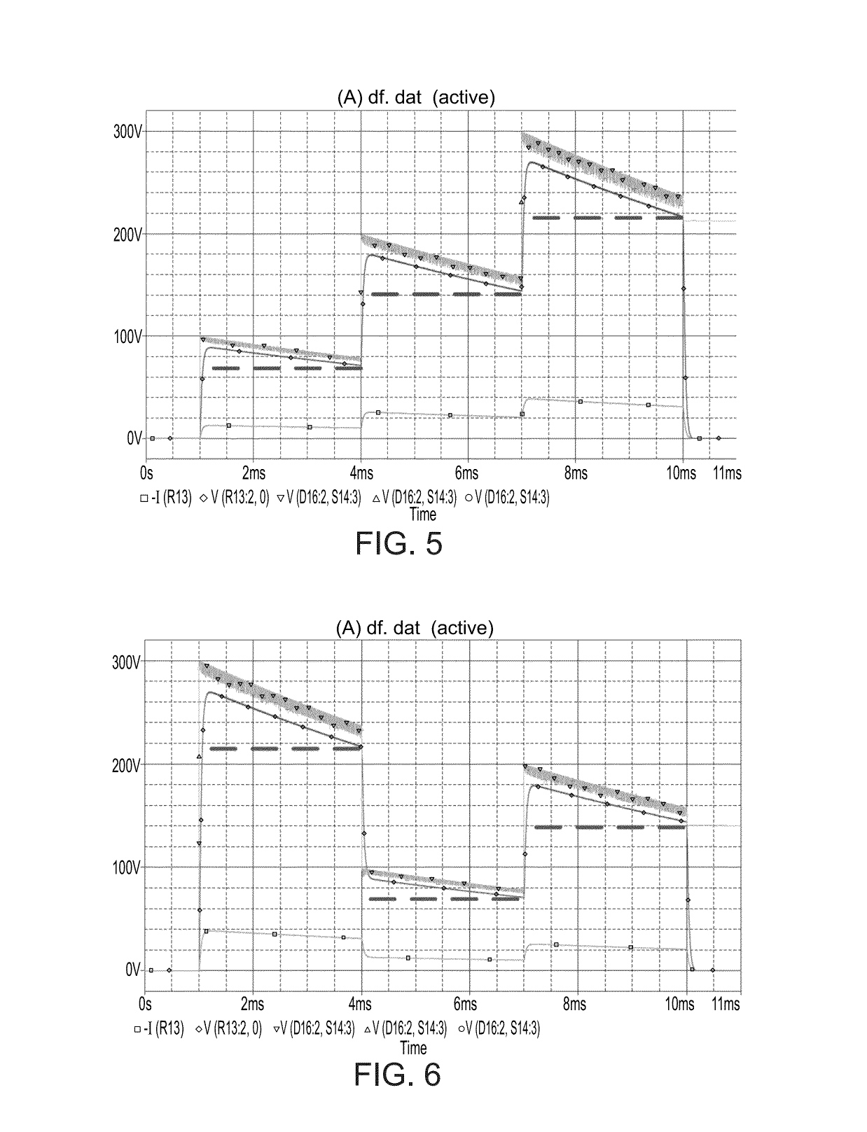

Reference is now also made to FIG. 4, which is a flowchart 400 of a method of generating a patterned pulse from a plurality of charges having an increased current, for example capacitor originated charges, according to some embodiments of the present invention. The method 400, which is optionally implemented by any of the PFNs which are depicted by any of FIGS. 1-3, is based, as shown at 401, on charging a plurality of capacitor units, such as shown at 101, with a plurality of charges. The charging that is optionally done with low current charges, loads the capacitor units 102 with a number of different increased current electrical charges. As shown at 402, a sequence defining a discharge order of a plurality of charges is provided, for example received from a computing unit, calculated and/or extracted from the memory. The order is defined according to a desired energizing pulse having a predetermined pattern. The predetermined pattern defines a multi-level voltage waveform such as a square waveform. The waveform includes a number of different voltages levels. The voltage level may increase, decrease and/or changed in a sinusoidal manner with time. Such a sequence, or instructions for generating such a sequence, may be referred to herein as discharging sequence.

Optionally, the discharging sequence is provided to the control unit 107, for example by hardware and/or software modules which are connected thereto.

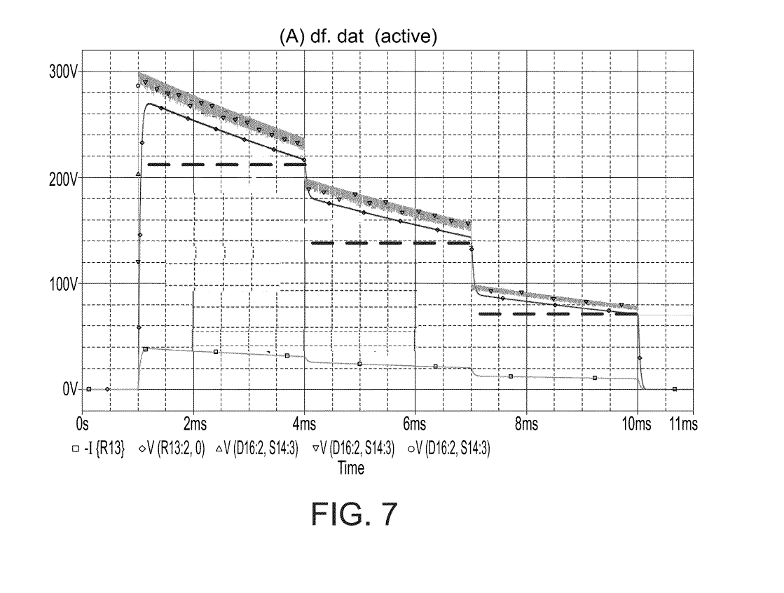

Now, as shown at 403, the plurality of charged capacitor units 102 are sequentially discharged, one at the time or one or more in each time, to a common load, via one or more electrical regulator(s), such as 103 or 303. The discharging is performed according to the discharging sequence. For example, in use, the control unit 107 opens and closes the switches 108 according to the discharging sequence. As shown at 404, this process may be repeated in any number of iterations. The discharging sequence may be changed or remained unchanged during the various iterations. The discharging sequence, which is performed via the one or more electrical regulator(s), such as 103 or 303, allows delivering energy in various patterns. For example, FIGS. 5, 6, and 7 are graphs depicting simulations of increasing, decreasing and increasing, and decreasing square waveforms which are generated according to the method depicted in FIG. 4 and/or by the PFNs which are depicted in FIGS. 1-3 (without the control unit). In these graphs, red sloping lines emulate the change in the voltage level during the delivery of each discharge via the one or more electrical regulators 103 (without the effect of the regulation), the green lines emulate the decrease in the change in the current during the delivery of each discharge via the one or more electrical regulators 103, and the brown dashed lines emulate an estimated voltage level of each one of the discharges after they have been regulated by the one or more electrical regulators.

According to some embodiments of the present invention, the PFN 100 includes a load switch (not shown) for connecting the one or more electrical regulators 103 to any of number of loads. In such an embodiment, the pulse with a regulated multi-level voltage waveform that is generated by the PFN 100 may be delivered to any of a number of loads, for example sequentially and/or or according to a user selection.

Optionally, the load switch controlled by the control unit 107.

Optionally, the control unit 107 adjusts the instructions sent to shape the regulated multi-level voltage waveform of the pulse, for example the instructions to the switches 108, to the electric regulators 103, and/or to the capacitor units 102, according to the load switch mode. In such a manner, different loads may be delivered with pulses having different regulated multi-level voltage waveforms.

According to some embodiments of the present invention, the control unit 107 is set to monitor the functionality of each one of the capacitor units 102. The monitoring is optionally performed by sampling the pulse generated by the PFN 100. Additionally or alternatively, the control unit 107 is set to monitor the functionality of each one of the electric regulators 103. Such monitoring is performed by sampling, the train pulses which are used to adjust the regulator.

In particular, the control unit 107, which may be a central control unit which controls all the modules or a set control units which are separately installed in the electric regulators 103 includes a pulse train regulation module that controls the output value (e.g., output voltage) of the electric regulators 103 by controlling the rate of regulating pulses. In a preferred embodiment, a continuous pulse train output from the control unit 103 is send to or at each electric regulator 103 according to the output charge of the capacitor units 102. The continuous pulse train operates at a high frequency, for example, 100 KHz. The control unit adjusts the rate and/or level of regulation according to the rate of the continuous pulse train.

Optionally, the rate of the continuous pulse train is fitted according to the sequence of operating the capacitor units. In such a manner, the electric regulator 103 is adjusted before the respective capacitor unit 102 is discharged. This assures that the discharges of the capacitor unit 102 are regulated even of the discharge rate is high.

Optionally, the control unit 107 is coupled to adjust the working output voltage of each electric regulator 103 according to forward feedback from a respective capacitor unit 102 or according to a backward feedback from the load 106.

Optionally, the control unit 107 is coupled to monitor a charging rate in some or all of the capacitor units 102 and outputs an indication which indicates which of the capacitor units, if any, does not charge properly. In some embodiments, the control unit 107 compares the waveform of the generated pulse with a reference pulse, such as a previously recorded waveform and/or reference waveform.

Optionally, waveforms of output pulses are sampled and recorded occasionally, in a synchronized or an unsynchronized manner, for example by the control unit 107 which is optionally connected to the output of the electric regulators 103. The recorded waveforms are used as reference waveforms which are matched with the waveform of the current pulse to determine its accuracy, for example by identifying one or more deviations in the pulse.

An analysis of a detected deviation may indicate which of the capacitor units to 102 which provide charges is not coordinated with one or more charges it has generated previously. As the discharging sequence of the capacitor units 102 is known, the analysis of the pulse may be used to evaluate, separately, the accuracy of each capacitor unit 102. If a deviation is detected in a segment of the waveform that is generated by the third charge, the capacitor unit 102 that has been operated in the third discharging session may malfunction and an indication may be outputted to the operator, for example by operating one or more indicative LEDs or a display which is connected to the control unit 107.

Optionally, the control unit 107 is coupled to monitor the train pulses which are used to fit the regulation level at the electric regulator 103 to the discharge of the capacitor unit 102. This monitoring allows receiving an indication about the functioning of the capacitor unit 101 which forwards its discharge to the electric regulator 103. In such a manner, the control unit 101 may notify the user about a malfunctioning capacitor unit 101 before the regulated energizing pulse which is generated by the PFN is even effected.

According to some embodiments of the present invention, the control unit 107 is connected to one or more sensors which monitor the functioning of the energized load 106. For example, if the load is a flash lamp, heat and/or illumination may be verified using a temperature sensor and/or a spectrometer and/or photodiode and if the load is a microwave oscillator, frequency stability may be checked using a frequency reader. In such embodiments, a control module that is designed to compute the regularity of the PFN 100 may be formed.

Optionally, the plurality of capacitor units 102 and/or the plurality of modules 101 are detachably connected to a supporting element, such as a board, which supports all the components of PFN 100. In such an embodiment, an operator may disconnected and replace any of the capacitor units 102 and/or the modules 101 when a malfunction is indicated by the control unit 107. This allows a laymen or an unskilled technician to maintain and/or repair the PFN 100 without having to send the PFN 100 and/or a device which contains the PFN 100 to a laboratory and/or without having to dispose the PFN 100 when not all the modules are defective.

It is expected that during the life of a patent maturing from this application many relevant devices and methods will be developed and the scope of the term a capacitor, an electric regulator, a switch and a supporting element is intended to include all such new technologies a priori.

As used herein the term “about” refers to ±10%.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” include plural references unless the context clearly dictates otherwise. For example, the term “a compound” or “at least one compound” may include a plurality of compounds, including mixtures thereof.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies to regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A pulse forming network (PFN), comprising:
at least one electrical regulator connected to a load;
a plurality of capacitor units adapted to store a plurality of charges in a plurality of working output voltages;
a plurality of switches, each adapted to couple electrically one of said plurality of capacitor units to said at least one electrical regulator; and
a control unit adapted to operate said plurality of switches to discharge said plurality of charges into said load, via said at least one electrical regulator, in sequence ordered to form a regulated energizing pulse having a desired multi-level voltage waveform.

2. (canceled)

3. The PFN of claim 1, wherein said at least one electrical regulator being adapted to regulate the level of each said working output voltage to a voltage level of no less than 90% of the minimum of said working output voltage when discharged into said at least one electrical regulator.

4. The PFN of claim 1, wherein said desired multi-level voltage waveform comprising said plurality of different working output voltages.

5. The PFN of claim 1, wherein said control unit monitors said pulse to identify a deviation from at least one of a reference pulse and a previously recorded pulse generated by said PFN.

6. The PFN of claim 3, wherein said control unit identifies a malfunction in at least one of said plurality of capacitor units according to an analysis of said waveform and outputs an indication which indicates which of said plurality of capacitor units malfunctions.

7. The PFN of claim 3, wherein said at least one electrical regulator is adjusted according to a train pulse which is adjusted according to a feedback control from at least one of said plurality of capacitor units, said control unit identifies a malfunction in at least one of said plurality of capacitor units according to an analysis of said train pulse and outputs an indication which indicates which of said plurality of capacitor units malfunctions accordingly.

8. The PFN of claim 1, wherein said plurality of capacitor units are detachably connected to a supporting structure.

9. The PFN of claim 1, wherein said control unit is adapted to trigger at least one of a number of said plurality of capacitor units simultaneously and said plurality of capacitor units sequentially.

10. (canceled)

11. The PFN of claim 1, wherein said control unit is adapted to monitor at least some of said plurality of capacitor units and to output an indication which indicates which of said plurality of capacitor units does not work properly.

12. A pulse forming network (PFN), comprising:
a plurality of capacitor units;
a plurality of charging units each electrically connected to another of said plurality of capacitor units, said plurality of charging units being adapted to charge said plurality of capacitor units with a plurality of electrical charges having a plurality of voltages;
at least one electrical regulator electrically connected to a load; and
a plurality of switches each coupling one of said plurality of capacitor units to said at least one electrical regulator and electrically connected to be controlled by a control unit.

13. The PFN of claim 12, wherein each said switch coupling one of said plurality of capacitor units via an anti reversing diode.

14. The PFN of claim 12, wherein said at least one electrical regulator comprises a plurality of electrical regulators, each said switch coupling one of said plurality of capacitor units to another of said plurality of electrical regulators.

15. The PFN of claim 12, wherein said plurality of capacitor units are adapted to be electrically charged with a plurality of different electrical charges.

16. The PFN of claim 12, wherein said plurality of switches are sequentially triggered to receive a respective said electrical charge from a respective said capacitor in a sequential order, forming a patterned energizing pulse.

17. The PFN of claim 16, wherein said patterned energizing pulse having a square waveform.

18. The PFN of claim 12, wherein said at least one electrical regulator comprises at least one of a voltage regulator and a current regulator.

19. (canceled)

20. The PFN of claim 12, further comprising a control unit, coupled to control said plurality of switches and adapted to trigger a number of said plurality of switches simultaneously.

21. (canceled)

22. The PFN of claim 12, wherein said control unit receive a requested charge level for said load and selects said number of switches according to said requested charge level.

23. The PFN of claim 12, further comprising a control unit, coupled to monitor a charging rate in each said capacitor and outputs an indication which indicates which of said plurality of capacitor units does not charge properly.

24. (canceled)

25. The PFN of claim 12, wherein said plurality of capacitor units are detachably connected to said PFN.

26. The PFN of claim 12, wherein each said capacitor is iteratively charged.

27. The PFN of claim 12, wherein said at least one electrical regulator comprises a buck converter.

28. (canceled)

29. (canceled)

30. A method of generating a patterned pulse, comprising:
a) charging a plurality of capacitor units with a plurality of charges; and
b) sequentially coupling said plurality of charged capacitor units to at least one electrical regulator so as to allow delivering a regulated energizing pulse having a desired multi-level voltage waveform to a load;
wherein said electrical regulator is connected to a load.

31. The method of claim 30, further comprising repeating said a) and b) so as to charge said load continuously.

32-37. (canceled)
